(19) United States
(12) Patent Application Publication
(10) Pub. No.: US 2005/0045909 A1
(43) Pub. Date: Mar. 3, 2005

(54) Electrostatic discharge protection for integrated circuit devices

(75) Inventor: Weimin Zhang, Singapore (SG)

Correspondence Address: NIXON & VANDERHYE, PC, 1100 N GLEBE ROAD, 8TH FLOOR, ARLINGTON, VA, 22201-4714, US

(73) Assignee: Agency for Science, Technology and Research, Singapore (SG)

(21) Appl. No.: 10/651,046

(22) Filed: Aug. 29, 2003

(51) Int. Cl. H01L 29/74

(52) U.S. Cl. 257/173

(57) ABSTRACT

An apparatus for providing ESD protection to an integrated circuit device comprising a substrate of one type of semiconductor, a first region of a complementary type of semiconductor formed in the substrate, which surrounds a second region of said one type of semiconductor. A plurality of diodes each is formed in one of the plurality of second regions. The at least one first region is disposed between the plurality of second regions and the substrate to prevent direct contact between the second regions and the substrate. The plurality of diodes are connectable in series for coupling to the integrated circuit device for providing ESD protection.

### FIELD OF THE INVENTION

The present invention relates to electrostatic discharge protection for electronic devices. In particular, it relates to electrostatic discharge protection structure for integrated circuit devices such as complementary metal oxide semiconductor (CMOS) devices.

### BACKGROUND OF THE INVENTION

Electrostatic discharge (ESD) commonly occurs during the manufacturing, handling and using of electronics devices, such as integrated circuit (IC) devices or chips. ESD may cause an electrical pulse that exceeds the withstanding limit of an IC chip and cause failure or damage of the device Effective ESD protection at each and every pin-out of an IC chip therefore becomes a key concern during the designing and manufacturing of IC chips.

A number of conventional methods are available for providing IC devices with ESD protection, some of which utilize diodes. FIG. 1A is a schematic diagram showing a general ESD protection scheme for an IC device 10 using diodes. The IC device 10 to which the ESD protection is to provide, shown as a two-stage inverter as an example, has an input 12 and an output 14.

A first pair of diodes 22 and 24 are coupled between the input 12 and V_{dd}/Vₛₛ. A second pair of diodes 32 and 34 are coupled between the output 14 and V_{dd}/Vₛₛ. A power clamp circuit 40 is coupled between V_{dd}/Vₛₛ to provide a downward discharge path from V_{dd} to Vₛₛ. The first and second pairs of diodes 22, 24, 32, and 34 are in the “off” status during normal operations of the IC device 10, and are turned on when an ESD occurs to discharge the ESD current away from the IC device 10.

In large signal application devices such as radio frequency power amplifiers (RFPA), signal swing of normal operations may exceed the turn-on voltage of a single diode. When used in an RFPA for ESD protection, this single diode may be turned-on, resulting in the leakage of the normal signal. Therefore, signal loss and/or distortion can occur which will seriously affect the normal operations of the IC device.

To provide effective ESD protection for large signal electronic devices, two or more diodes may be stacked in series to increase the overall turn-on voltage to prevent signal loss and/or distortion during normal operations. One example of this approach is disclosed in U.S. Pat. No. 5,528,189 issued to Khatibzadeh. In this patent, a diode string of two or more diodes connected in series is provided to protect transistor avalanche breakdown. Unfortunately, the attempt of directly connecting two or more diodes in series faces difficulties and problems in CMOS technology.

In standard CMOS technology, components such as diodes are formed into two types, i.e. N+/P-sub diodes in a P-substrate, and P+/N-well diodes in N-well. In the first type as shown in FIG. 1B, N+/P-sub diodes 51 cannot be connected in series because the P-substrate is shared by all the diodes. In the second type as shown in FIG. 1C, it is possible to connect P+/N-well diodes 52 in series. Unfortunately, due to the structural nature, corresponding parasitic diodes 54 formed by the N-well and the P-substrate create direct discharge paths between N-node of the P+/N-well diode 52 and the P-substrate. When the diodes 52 are connected in series in an attempt of providing ESD protection for large signal electronic devices, and in the event that there is a negative signal swing at the N-node of the P+/N-well diode 52 exceeding the turn-on limit of a single parasitic diode 54, the parasitic diode 54 will be inevitably turned-on hence cause the leakage of normal signal to the P-substrate. As such, connecting P+/N-well diodes in series with is not suitable to provide ESD protection for relatively large signal electronic devices.

Accordingly, there is a need to provide a modified structure in which diodes can be connected in series and in the mean time, the signal leakage from the diodes to the substrate can be reduced so that the serially connected diodes can achieve a higher turn-on voltage for providing ESD protection to devices with an operational signal level higher than the turn-on voltage of a single diode.

### SUMMARY OF THE INVENTION

In accordance with a first aspect of the present invention, there is provided an apparatus for providing ESD protection to an integrated circuit d vice. The apparatus comprises a substrate made of a first type of semiconductor, a first region of a complementary type of semiconductor formed in the substrate, and a plurality of second regions of said one type of semiconductor formed in the first region. In each of the plurality of second regions, there is formed a diode. The first region is disposed between the plurality of second regions and the substrate and therefore, the plurality of second regions do not directly contact the substrate so that signal leakage to the substrate is reduced. The plurality of diodes can be selectively connected in series for coupling to the integrated circuit device to provide ESD protection thereto.

In one embodiment, the at least one first region further comprises a plurality of first well structures disposed between the plurality of second regions and the substrate to prevent direct contact between the plurality of second regions and the substrate.

In one embodiment, the first well structure further comprises a deep well structure disposed underneath the bottom of the second regions.

In one embodiment, the substrate is a P-type semiconductor substrate, the first well structure comprises deep N-wells and N-wells formed in the P-type substrate, and the second regions comprise P-wells formed in the deep N-wells and N-wells. Each of the plurality of diodes is formed in one P-well.

Each one of the plurality of second regions and the first region form a parasitic diode, and each one of the plurality of second regions, the first region and the substrate form a bipolar device. The bipolar device is coupled between the parasitic diode and the substrate, so that a current leakage from the parasitic diode to the substrate is reduced.

In accordance with a second aspect of the present invention, there is provided an integrated circuit device with on-chip ESD-protection circuits. The device comprises a substrate, a functional module formed on the substrate and a plurality of diodes formed in a plurality of a second well structures of the substrate. A first well structure is disposed between the plurality of the second well structures and the substrate for preventing direct connection or contact between the second well structures and the substrate. Signal leakage between the diodes and the substrate is reduced, therefore the diodes are capable to be connected in series to form a diode string. The diode string has an increased overall turn-on voltage which is higher than the operational signal level of the functional module so that during normal operation, the diode string will not be turned on to leak normal signals.

In accordance with a third aspect of the present invention, there is provided a diode device for protecting an integrated circuit against ESD. The diode device comprises a semiconductor substrate, at least one first region formed in the substrate from a first semiconductor material and substantially surrounding at least one second region of a complementary semiconductor material The device comprises a diode, having an N-node and a P-node, formed in the second region.

The substrate, the first region and the second region form a bipolar device coupled between the diode and the substrate to prevent direct connection between the diode and the substrate.

The present invention advantageously utilizes well/deep well structure to prevent direct contact or connection between the P-N structure of diode and the substrate and overcome the problem of signal leakage due to the parasitic diodes in CMOS technology. Diodes are successfully connected in series in CMOS technology to provide ESD protection for devices with signal applications level higher than the turn-on voltage of a single diode.

### BRIEF DESCRIPTION OF THE DRAWINGS

These and other aspects and advantages of the present invention will be described in detail with reference to the accompanying drawings, in which:

FIG. 1A is a schematic diagram illustrating a conventional solution of ESD protection;

FIG. 1B is a partial cross-sectional view showing one conventional type of diodes formed in a semiconductor device;

FIG. 1C is a partial cross-sectional view showing another conventional type of diodes formed in a semiconductor device;

FIG. 2A is a partial cross-sectional view showing an ESD protection apparatus according to one embodiment of the present invention;

FIG. 2B is the circuit diagram of FIG. 2A;

FIG. 2C is a partial cross-sectional view showing an ESD protection apparatus according to another embodiment of the present invention; and

FIG. 3 is a schematic diagram showing an ESD protection circuit according to the present invention.

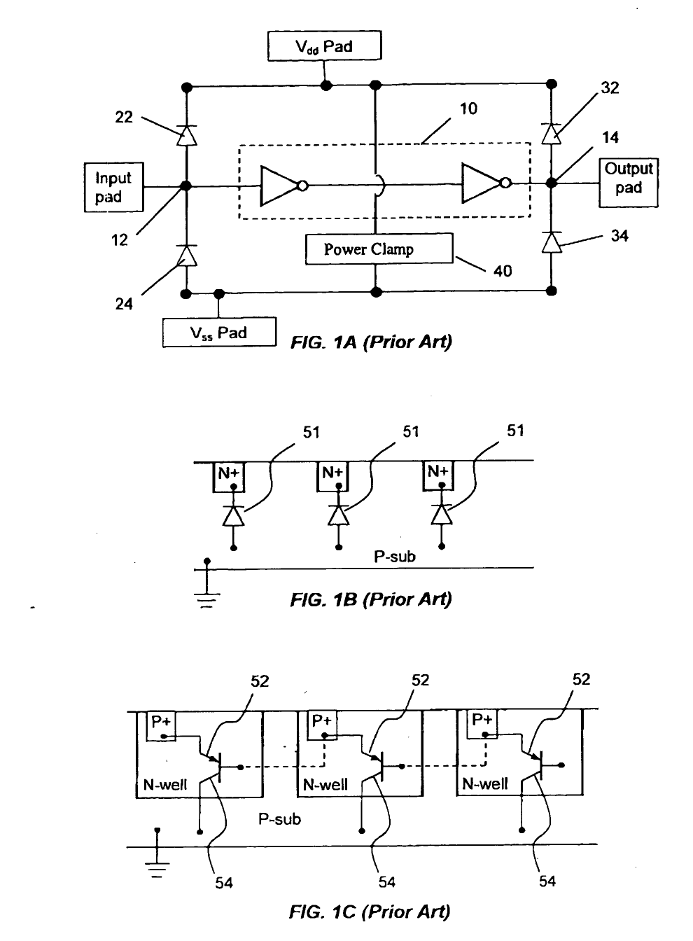

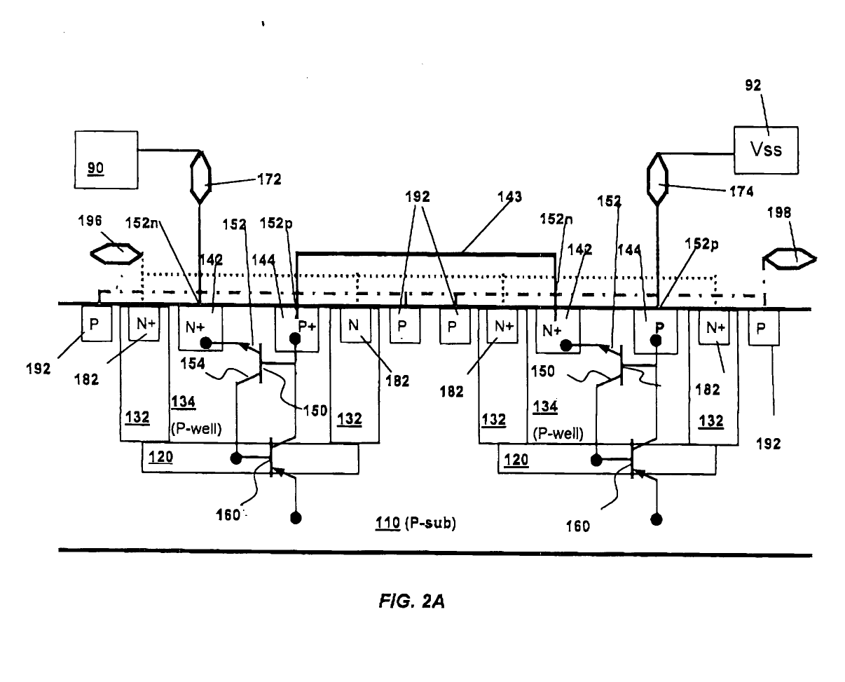

### DETAILED DESCRIPTION OF THE PREFERRED EMBODIMENTS

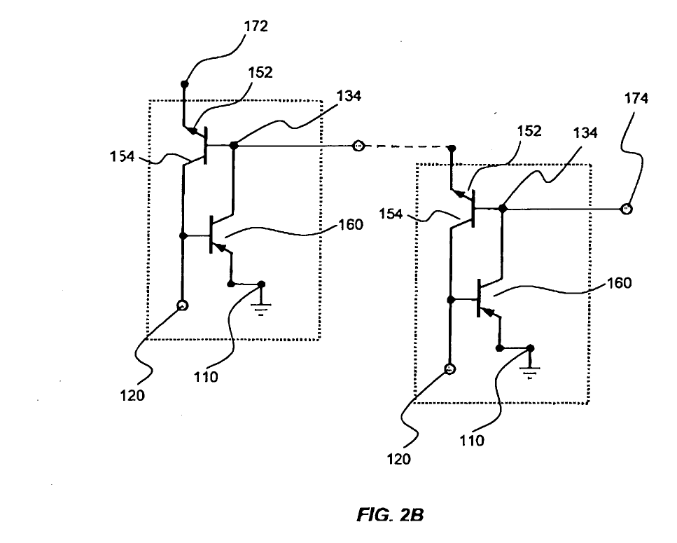

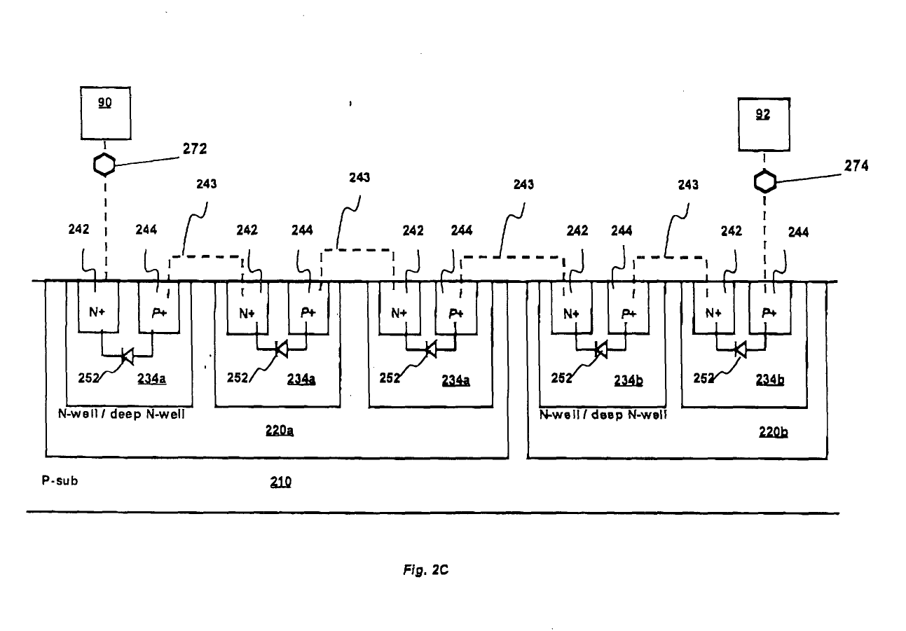

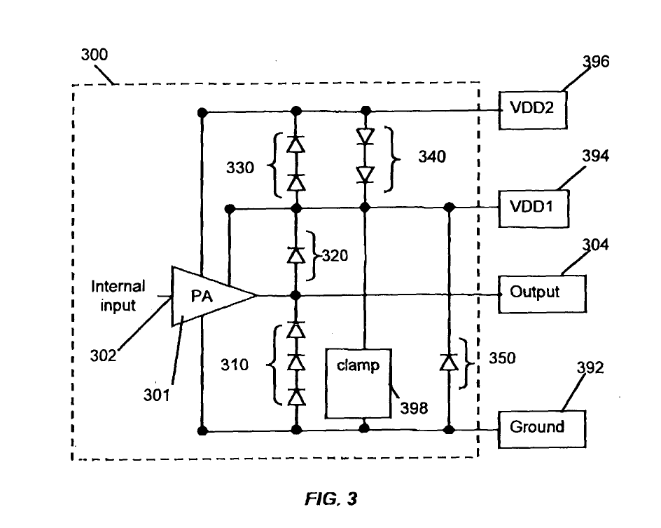

As shown in FIGS. 2A and 2B, an ESD protection apparatus 100 for a semiconductor device 90 (such as a CMOS device) according to one embodiment of the present invention comprises a semiconductor substrate 110, such as a P-type semiconductor. A plurality of deep N-wells 120 and N-wells 132 are formed on the substrate 110. A plurality of P-wells 134 are formed in each deep N-well 120 and N-wells 132. Although only two P-wells 134 are shown for ease of illustration, many additional P-wells may be formed, either in the same or separate deep N-wells/N-wells. One pair of N+ and P+ regions 142, 144 is formed in each one of the plurality of P-well 134.

N+ and P+ regions 142, 144 in each P-well 134 form diodes 152, each having an N-node 152n and a P-node 152p. Formed by P+ regions 144/P-wells 134 and deep N-wells 120/N-wells 132 are parasitic diodes 154. Each diode 152 and parasitic diode 154 form an NPN bipolar 150. Similarly, formed by P+ regions 144/P-wells 134, deep N-wells 120/N-wells 132 and P-substrate 110 are PNP bipolars 160.

Two or more diodes 152 are connected in series with the N-node of one diode connecting the P-node of a preceding diode through an internal connection 143 to form a diode string. It should be appreciated that although only two diodes 152 are shown, other numbers of diodes 152 can also be connected in series in the similar manner.

P-node 152p of a first diode 152 of the diode string is drawn out as a diode series group P-node 174, and N-node 152n of the last diode of the diode string is drawn out as a diode series group N-node 172. Group P-node 174 and group N-node 172 can be connected between a pad or pin of the semiconductor device 90 and a V_{SS} 92 to provide ESD protection.

According to this embodiment, deep N-wells 120 and N-wells 132 are formed between P-wells 134 and substrate 110, hence there is no direct contact or connection between P-wells 134 and substrate 110. According to this structure, parasitic diodes 154 are not connected to substrate 110 directly, but are coupled to deep N-well 120/N-well 132. Between substrate 110 and each diodes 152/parasitic diode 154 there are coupled parasitic PNP bipolars 160.

When there is a negative swing at group N-node 172 higher than the turn-on voltage limit of a single diode 152, the parasitic diodes 154 will not be turned on because, firstly, in normal applications deep N-well 120 1 N-well 132 are either positively biased or floating. Secondly, P-well potential is generally negative. For these two reasons, diodes 152 are positively biased and parasitic diodes 154 are generally reverse biased. This makes possible that when the series-connected diodes 152 are used for the ESD protection purpose, and when there is a negative swing at group N-node 172 higher than the turn-on limit of a single diode 152, the signal leakage through parasitic diodes 154 to substrate 110 can be greatly suppressed.

In one example as according to experiment measurements, three diodes are connected in series to form a diode string according to the above embodiment. Each single diode has a turn-on voltage of about 0.6 to 0.7 V, and the diode string achieves an increased turn-on voltage of about 1.65 V. Further experiment results show that strings of four and five diodes can achieve increased turn-on voltages of 2.05 V and 2.35 V, respectively.

N+ regions 182 are formed in the N-wells 132 to provide electrical contacts, which may be connected together to N-wells tap ring 196. Similarly, P+ regions 192 may be formed in P-substrate surrounding N-wells 132 to provide electrical contacts, through which a P-substrate tap ring 198 is drawn and connecting the P+ regions 192 to the ground.

Reference is now made to FIG. 2C. An ESD protection apparatus according to another embodiment of the present invention comprises a P-type semiconductor substrate 210, two N-well/deep N-well regions 220a and 220b are formed on the substrate 210 N-well/deep N-well region 220a surrounds three P-wells 234a Each P-well 234a has formed therein N+ region 242 and P+ region 244 which form a diode 252. N-well/deep N-well region 220b surrounds two P-wells 234b. Each P-well 234b has also formed therein N+ region 242 and P+ region 244 which forms a diode 252. In this embodiment, more than one N-well/deep N-well regions are formed in the substrate, and more than one P-wells are formed in each single N-well/deep N-well region. Diodes 252 formed in each P-well 234a and 234b are connectable in series through connections 243 to form a diode string, and the N-well/deep N-well region(s) prevent the direct connection or contact between diodes 252 and substrate 210. A first node 272 and a second node 274 of the diode string can then be connected between an input/output pad or pin of an electronic device 90 and a Vss 92 to provide ESD protection.

Based on the signal level of normal operation and the ESD protection requirement, the number of diodes serially connected in one or more diode strings may be determined. In one application shown in FIG. 3 below, diode strings of one, two arid three are utilized for ESD protection.

FIG. 3 is a schematic diagram showing an on-chip ESD protection circuit according to one embodiment of the present invention, for a large signal Radio Frequency Power Amplifier (RFPA) based on commercial 0.18 micrometer CMOS technology. A CMOS device 300 comprises a functional module, such as an RFPA 301 having an input 302 and an output 304. A first diode string 310 formed of three diodes is coupled between the output 304 and the ground 392 to support negative swing of large output signal. A second diode string 320 of one diode is coupled between the output 304 and the VDD1 394 to preserve positive signal swing as N-node of the diode is biased to 1.8 V. A third diode string 330 of two diodes, and a fourth diode string 340 of two diodes are coupled between the two VDD lines VDD1 394 and VDD2 396. All the diodes and diode strings used in this embodiment are formed according to the structure as described in FIG. 2

In this example, VDD is 1.8 V DC and the third diode string 330 and the fourth diode string 340 are coupled between the two VDD lines to ensure no current flow therebetween during the supply of the DC voltages. A power clamp circuit 398 is coupled between the VDD1 394 and the ground to provide a downward discharge path. A fifth diode string 350 of a single diode is coupled between the VDD1 394 and the ground to provide a short and quick upward discharge path.

Although embodiments of the present invention have been illustrated in conjunction with the accompanying drawings and described in the foregoing detailed description, it should be appreciated that the invention is not limited to the embodiments disclosed, and is capable of numerous rearrangements, modifications, alternatives and substitutions without departing from the spirit of the invention as set forth and recited by the following claims.

1. An apparatus for providing ESD protection to an integrated circuit device, comprising:
a substrate of one type of semiconductor;
at least one first region of a complementary type of semiconductor formed in the substrate;
a plurality of second regions of said one type of semiconductor formed in the at least one first region;
a plurality of diodes one each formed in one of the plurality of second regions;
wherein the at least one first region is disposed between the plurality of second regions and the substrate to prevent direct contact therebetween; and
wherein the plurality of diodes are connectable in series for coupling to the integrated circuit device to provide ESD protection thereto.

2. The apparatus as recited in claim 1, wherein the at least one first region further comprises a plurality of first well structures disposed between the plurality of second regions and the substrate to prevent direct contact therebetween.

3. The apparatus as recited in claim 2, wherein the first well structures further comprises a deep well structure disposed underlying the second regions.

4. The apparatus as recited in claim 3, wherein the substrate is a P-type semiconductor substrate, the first well structure comprises deep N-wells and N-wells formed in the P-type substrate, and the second regions comprise P-wells formed in the deep N-wells and N-wells, wherein each of the plurality of diodes is formed in one P-well.

5. The apparatus as recited in claim 1, wherein each one of the plurality of second regions and the at least one first region form a parasitic diode, and each one of the plurality of second regions, the at least one first region and the substrate form a bipolar device coupled between the parasitic diode and the substrate to reduce a current leakage from the parasitic diode to the substrate.

6. The apparatus as recited in claim 5, wherein each of the plurality of diodes is positively biased.

7. The apparatus as recited in claim 5, wherein the first region is floating.

8. The apparatus as recited in claim 5, wherein the first regions is positively biased.

9. A CMOS integrated circuit device comprising:
a substrate;
a functional module formed on the substrate, the functional module having an operational signal level;
a plurality of diodes each being formed in each of a plurality of second well structures on the substrate;
a first well structure disposed between the plurality of second well structures and the substrate for preventing direct connection between the second well structures and the substrate to reduce a signal leakage therebetween; and
wherein the plurality of diodes are selectively connectable in series to form at least one diode string, and the diode string has a turn-on voltage higher than the operational signal level of the functional module.

10. The device as recited in claim 9, wherein the substrate is a P-type substrate, the first well structure comprises a deep N-well and an N-well, and the second well structure is a P-well.

11. The device as recited in claim 10, wherein the deep N-well structure further comprises a plurality of separate deep N-wells, wherein each of the plurality of deep N-wells is disposed between a corresponding one of the plurality of P-wells and the substrate.

12. The device as recited in claim 9, wherein each one of the plurality of second well structures and the first well structure form a parasitic diode, and each one of the plurality of second well structures, the first well structure and the substrate form a bipolar device coupled between the parasitic diode and the substrate to reduce a current leakage from the parasitic diode to the substrate.

13. The device as recited in claim 12, wherein each of the plurality of diodes is positively biased.

14. The device as recited in claim 12, wherein the first well structure is floating.

15. The device as recited in claim 12, wherein the first well structure is positively biased.

16. A diode device for protecting an integrated circuit against ESD comprising.
a semiconductor substrate;
at least one first region formed in the substrate from a first semiconductor material and substantially surrounding at least one second region of a complementary semiconductor material; and
a diode, having an N-node and a P-node, formed in the second region.

17. The diode device as recited in claim 16 comprising one or more first regions, each said first region substantially surrounding two or more second regions, there being a diode formed in each said second region, wherein said diodes are connectable in series to provide ESD protection.

18. The diode device as recited in claim 16 comprising two or more first regions each surrounding a single second region, there being a diode formed in each said second region, wherein said diodes are connectable in series to provide ESD protection.

19. The diode device as recited in claim 16, wherein the substrate, the first region and the second region form a bipolar device coupled between the diode and the substrate to prevent direct connection between the diode and the substrate.

20. The diode device as recited in claim 16, wherein the first region is formed form a well structure and an underlying deep well structure.

21. The diode device as recited in claim 16, wherein the substrate and the second region are formed of P-type semiconductor material and the first region is formed of N-type semiconductor material.

22. The diode device as recited in claim 21, wherein the first region is formed from N-wells and underlying deep N-wells.
